(19) United States
(12) Patent Application Publication
(10) Pub. No.: US 2007/0278554 A1
(43) Pub. Date: Dec. 6, 2007

(54) Semiconductor memory device and method of forming the same

(75) Inventors: Ki-Whan Song, Seoul (KR); Young-Ok Cho, Seongnam-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/730,306

(22) Filed: Mar. 30, 2007

(30) Foreign Application Priority Data
Jun. 1, 2006 (KR) 10-2006-0049425

(51) Int. Cl. H01L 29/76; H01L 29/06

(52) U.S. Cl. 257/314; 257/618

(57) ABSTRACT

Example embodiments are directed to a semiconductor memory device that may include a plurality of memory cells, each having a transistor of a first conductivity type with a first shape, a sub-word line driver including a transistor of the first conductivity type with a second shape and a transistor of a second conductivity type with the second shape, a sense amplifier including a transistor of the first conductivity type with the second shape and a transistor of the second conductivity type with the second shape, and a peripheral circuit including a transistor of the first conductivity type with the second shape and a transistor of the second conductivity type with the second shape in order to control inputting/outputting of data to/from the memory cells.

This application claims the benefit of Korean Patent Application No. 2006-49425, filed Jun. 1, 2006, the entire contents of which are hereby incorporated herein by reference.

### BACKGROUND OF THE INVENTION

1. Field

Example embodiments relate to a semiconductor memory device and, more particularly, to a semiconductor memory device having transistors of different shapes, and a method of forming the same.

2. Description of Related Art

As semiconductor memory devices become more highly integrated and consume less power, short channel effects may occur more frequently in core circuits, for example, in an n-type MOS transistor of a memory cell. This may reduce the operating reliability and data retention time of the memory cell.

Conventional semiconductor memory devices have attempted to remedy the aforementioned problems by applying a back bias voltage; for example, applying a negative voltage to the bulk of an n-type MOS transistor in the memory cell. An increase in threshold current of the n-type MOS transistor in a turned-off state due to the application of a back bias voltage may be prevented by adopting a negative word line driver.

On the other hand, a peripheral circuit, being less integrated, may receive a higher voltage than the core circuit, and an n-type MOS transistor of the peripheral circuit may not be as affected by short channel effects. Accordingly, a ground voltage higher than the back bias voltage may be applied to the bulk of the n-type MOS transistor of the peripheral circuit.

In other words, a conventional semiconductor memory device may be structured such that the negative back bias voltage may be applied to the bulk of the n-type MOS transistor of the core circuit, while the ground voltage may be applied to the bulk of the n-type MOS transistor of the peripheral circuit.

FIG. 1 is a circuit diagram illustrating a core circuit of a conventional semiconductor memory device.

Referring to FIG. 1, the core circuit may include a cell array 11, a sense amplifier 12, a negative sub-word line driver 13, and a conjunction circuit 14.

The cell array 11 may include a plurality of memory cells MC, each of which may have a capacitor C and an n-type MOS transistor NM1, to the bulk of which a back bias voltage VBB may be applied. The sense amplifier 12 may include an n-type sense amplifier nSA, an input/output selection circuit IOS, and a p-type sense amplifier pSA. For example, the n-type sense amplifier nSA may include n-type MOS transistors NM2 and NM3, where the back bias voltage VBB may be applied to the bulk of each. The input/output selection circuit IOS may include n-type MOS transistors NM4 and NM5, where the back bias voltage VBB may be applied to the bulk of each. The p-type sense amplifier pSA may include p-type MOS transistors PM1 and PM2, where a boosting voltage VPP or power supply voltage VDD may be applied to the bulk of each.

The negative sub-word line driver 13 may include a plurality of word line drivers WLD, each of which may include n-type MOS transistors NM6 and NM7, where the back bias voltage VBB may be applied to the bulk of each. In addition, the negative sub-word line driver 13 may include a p-type MOS transistor PM3, where the boosting voltage VPP or the power supply voltage VDD may be applied to the bulk.

The conjunction circuit 14 may include an n-type sense amplifier control circuit nSAC, a p-type sense amplifier control circuit PSAC, and a word line for boosting the signal generation circuit PXiG. For example, the n-type sense amplifier control circuit nSAC may include an n-type MOS transistor NM8 to the bulk of which the back bias voltage VBB may be applied, and the p-type sense amplifier control circuit PSAC may include a p-type MOS transistor PM4 to the bulk of which the boosting voltage VPP or power supply voltage VDD may be applied. Also, the word line boosting signal generation circuit PXiG may include two inverters. Although not shown in the drawings, each of the inverters may include a p-type MOS transistor and an n-type MOS transistor, where the back bias voltage VBB may be applied to the bulk of each.

In the above-described conventional semiconductor memory device, the core circuit may be configured with p-type transistors and n-type transistors, and the back bias voltage VBB may be applied to the bulk of each of the n-type transistors.

Although not shown in the drawings, a peripheral circuit may also be configured with a plurality of n-type MOS transistors and a plurality of p-type MOS transistors. As mentioned above, however, a ground voltage VSS may be applied to the bulk of each of the n-type MOS transistors of the peripheral circuit.

FIG. 2 illustrates an example substrate bias structure of the semiconductor memory device shown in FIG. 1.

In FIG. 2, a region hatched with oblique lines may refer to a deep n-well, a region hatched with dots may refer to an n-well, a region hatched with crosses may refer to a p-well, and an unhatched region may refer to a semiconductor substrate p-sub.

The deep n-well for forming a core circuit may be located in the semiconductor substrate p-sub. P-wells CELL, to which a back bias voltage VBB may be applied, and in which the n-type MOS transistors of the cell array 11 may be formed, may be arranged in a matrix on the deep n-well.

P-wells nSA, to which the back bias voltage VBB may be applied, and in which the n-type MOS transistors of the sense amplifier 12 may be formed, may be disposed on the deep n-well in a widthwise direction of the p-well CELL of the cell array 11. Thus, the p-wells nSA may be spaced apart from the p-well CELL of the corresponding cell array 11, and may be adjacent to the p-well CELL of the adjacent cell array 11.

P-wells nSWD, to which the back bias voltage VBB may be applied, and in which the n-type MOS transistors of the sub-word line driver 13 may be formed, may be disposed on the deep n-well in a lengthwise direction of the p-well CELL of the cell array 11. Thus, the p-wells nSWD may be adjacent to the p-well CELL of the corresponding cell array 11, and may be spaced apart from the p-well CELL of the adjacent cell array 11.

P-wells nCON, to which the back bias voltage VBB may be applied, and in which the n-type MOS transistor of the conjunction circuit 14 may be formed, may be disposed on the deep n-well in a lengthwise direction of the sense amplifier 12. Thus, the p-wells nCON may be adjacent to the p-well nSA of the corresponding sense amplifier 12, and may be spaced apart from the p-well nSWD of the corresponding sub-word line driver 13.

N-wells pSA, in which the p-type MOS transistors of the sense amplifier 12 may be formed, may be disposed on the deep n-well between the cell array 11 and both the p-wells CELL and the p-wells nSA of the sense amplifier 12.

N-wells PSWD, in which the p-type MOS transistors of the sub-word line driver 13 may be formed, may be disposed on the deep n-well between the cell array 11 and both the p-wells CELL and the p-wells nSWD of the sub-word line driver 13.

N-wells pCON, in which the n-type MOS transistor of the conjunction circuit 14 may be formed, may be disposed on the deep n-well between the sub-word line driver 13 and both the p-wells nSWD and the p-wells nCON of the conjunction circuit 14.

Also, a dummy p-well “dummy” may further be disposed on the deep n-well to surround the entire outer region of the core circuit. Thus, a portion of the semiconductor substrate p-sub in which the core circuit may be formed may be electrically isolated from a portion of the semiconductor substrate p-sub in which the peripheral circuit may be formed.

A p-well nPERI, to which the ground voltage VSS may be applied, and in which the n-type MOS transistors of the peripheral circuit may be formed, and an n-well pPERI, in which the p-type MOS transistors of the peripheral circuit may be formed, may be disposed in a portion of the semiconductor substrate p-sub in which the deep n-well is not formed.

In the semiconductor memory device shown in FIG. 1, the p-wells CELL, nSA, nSWD, and nCON of the cell array 11, the sense amplifier 12, the sub-word line driver 13, and the conjunction circuit 14 may be electrically connected to one another and may receive the same voltage, for example, the back bias voltage VBB. On the other hand, the p-well nPERI of the peripheral circuit may be electrically isolated from the p-wells CELL, nSA, nSWD, and nCON, and may receive a different voltage, i.e., the ground voltage VSS.

FIG. 3 is a cross-sectional view taken along line Y-Y′ shown in FIG. 2. FIG. 3 illustrates the cell array, the sub-word line circuit, and the peripheral circuit of FIG. 2.

Referring to FIG. 3, the p-well nSWD of the cell array 11 and the p-well nSWD of the negative sub-word line driver 13 may be disposed adjacent to each other on the deep n-well, and may receive the same back bias voltage VBB. However, the p-well nPERI of the peripheral circuit may be electrically isolated from the p-well nSWD of the cell array 11 and the p-well nSWD of the negative sub-word line driver 13 by the deep n-well and the n-well PSWD of the negative sub-word line driver 13, and may receive the ground voltage VSS.

As described above, the conventional semiconductor memory device may have a bulk voltage of the n-type MOS transistor different in the core circuit than in the peripheral circuit, and thus, may minimize short channel effects and the generation of threshold current in the core circuit, including the memory cell using the negative sub-word line driver. The conventional semiconductor memory device may thereby attempt to improve the operating reliability and data retention time of a memory cell.

However, the voltage applied to the bulk of the n-type MOS transistor may cause a body effect, leading to a change in threshold voltage for the n-type MOS transistor of the core circuit.

Accordingly, it may be necessary to perform a Vt-adjust ion implantation process on all the n-type MOS transistors of the cell array 11, the sense amplifier 12, the sub-word line driver 13, and the conjunction circuit 14, so that the threshold voltages of the n-type MOS transistors of the core circuit may be nearly equal to the threshold voltage of the n-type MOS transistors of the peripheral circuit.

Therefore, although the conventional semiconductor memory device may improve the operating reliability and data retention time of a memory cell, the number of circuits subject to Vt-adjust ion implantation may increase significantly, which may make the entire fabrication process more complicated.

### SUMMARY OF THE INVENTION

Example embodiments are directed to a semiconductor memory device that may improve operating reliability and data retention time of memory cells and reduce the number of circuits for performing a Vt-adjust ion implantation process, and a method of forming the same.

According to example embodiments, a semiconductor memory device may include a plurality of memory cells, a sub-word line driver, a sense amplifier, and a peripheral circuit. The plurality of memory cells may each have a transistor of a first conductivity type with a first shape. The sub-word line driver may include a transistor of the first conductivity type with a second shape and a transistor of a second conductivity type with the second shape. The sense amplifier may include a transistor of the first conductivity type with the second shape and a transistor of the second conductivity type with the second shape. The peripheral circuit may include a transistor of the first conductivity type with the second shape and a transistor of the second conductivity type with the second shape, in order to control inputting/outputting of data to/from the memory cells. The transistor of the first conductivity type with the first shape, the transistor of the first conductivity type with the second shape in the peripheral circuit, and the transistor of the first conductivity type with the second shape in the sense amplifier may have the same bulk voltage. However, the transistor of the first conductivity type with the second shape in the sub-word line driver may have a negative bulk voltage lower than the bulk voltage of the transistor of the first conductivity type with the first shape.

The transistor with the first shape may be a vertical channel transistor (VCT), which may include a source region (or drain region) disposed on the first well of the second conductivity type, a channel region disposed on the source region (or drain region), a drain region (or source region) disposed on the channel region, and a gate electrode surrounding the channel region. Alternatively, the transistor with the first shape may be a fin field effect transistor (FinFET), which may include a fin active region connected to the first well of the second conductivity type and may protrude from the top surface of the first well of the second conductivity type, a gate electrode surrounding a channel region disposed in the fin active region, and a source region and a drain region disposed in the fin active region on both sides of the gate electrode.

The transistor with the second shape may be a MOS transistor.

The transistor of the second conductivity type with the second shape in the sub-word line driver may apply a voltage to the gate of the transistor of the first conductivity type with the first shape in order to turn it on. The transistor of the first conductivity type with the second shape in the sub-word line driver may receive a negative voltage as a bulk voltage and may apply the negative bulk voltage to the gate of the transistor of the first conductivity type with the first shape in order to turn it off.

According to example embodiments, a semiconductor memory device may further include a deep well and first, second, and third wells. The deep well may be of the first conductivity type and may be disposed in a semiconductor substrate of the second conductivity type. The first well may be of the second conductivity type and may be disposed on the deep well of the first conductivity type. A transistor of the first conductivity type with a first shape of a memory cell and a transistor of the first conductivity type with the second shape of the sense amplifier may be formed in the first well. A second well of the second conductivity type may be electrically isolated from the first well of the second conductivity type and may be disposed on the deep well. The transistor of the first conductivity type with the second shape of the sub-word line driver may be formed in the second well. A third well of the second conductivity type may be electrically isolated from both the first well of the second conductivity type and the second well of the second conductivity type, and may be disposed in the semiconductor substrate. The transistor of the first conductivity type with the second shape of the peripheral circuit may be formed in the third well. A first voltage may be applied to the first well of the second conductivity type and the third well of the second conductivity type. A negative voltage lower than the first voltage may be applied to the second well of the second conductivity type.

The transistor with the first shape may be a VCT, which may include one of a source region and a drain region disposed on the first well of the second conductivity type, a channel region disposed on the source region or the drain region, the other of the drain region and the source region disposed on the channel region, and a gate electrode surrounding the channel region. Alternatively, the transistor with the first shape may be a FinFET, which may include a fin active region of the second conductivity type connected to the first well of the second conductivity type and protruding from a top surface of the first well of the second conductivity type, a gate electrode surrounding a channel region disposed in the fin active region, and a source region and a drain region disposed in the fin active region on both sides of the gate electrode.

The transistor with the second shape may be a MOS transistor.

The semiconductor memory device may also include additional wells. A first well of the first conductivity type may be disposed on the deep well between the first well of the second conductivity type and the second well of the second conductivity type to electrically isolate the first well of the second conductivity type from the second well of the second conductivity type. A transistor of the second conductivity type with the second shape included in the sub-word line driver may be formed in the first well of the first conductivity type. A second well of the first conductivity type may be disposed on the deep well adjacent to the first well of the second conductivity type. A transistor of the second conductivity type with the second shape included in the sense amplifier may be formed in the second well of the first conductivity type. A third well of the first conductivity type may be electrically isolated from the first well of the first conductivity type and the second well of the first conductivity type, and may be disposed in the semiconductor substrate. A transistor of the second conductivity type with the second shape included in the peripheral circuit may be formed in the third well of the first conductivity type.

A method of forming a semiconductor device according to example embodiments may include forming a deep well of a first conductivity type in a semiconductor substrate of a second conductivity type. A transistor of the first conductivity type with a first shape of a memory cell and a transistor of the first conductivity type with a second shape of a sense amplifier may be formed in a first well of the second conductivity type on the deep well of the first conductivity type. A transistor of the first conductivity type with the second shape of a sub-word line driver may be formed in a second well of the second conductivity type, electrically isolated from the first well of the second conductivity type, on the deep well of the first conductivity type. A transistor of the first conductivity type with the second shape of a peripheral circuit may be formed in a third well of the second conductivity type, electrically isolated from the first well of the second conductivity type and the second well of the second conductivity type, in the semiconductor substrate. The transistor of the first conductivity type with the first shape, the transistor of the first conductivity type with the second shape in the peripheral circuit, and the transistor of the first conductivity type with the second shape in the sense amplifier may have the same bulk voltage, and the transistor of the first conductivity type with the second shape in the sub-word line driver may have a negative bulk voltage lower than the bulk voltage of the transistor of the first conductivity with the first shape.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a circuit diagram of a portion of a core circuit of an example conventional semiconductor memory device.

FIG. 2 illustrates an example substrate bias structure of the semiconductor memory device shown in FIG. 1.

FIG. 3 is a cross-sectional view taken along line Y-Y′ shown in FIG. 2, which illustrates an example cell array, sub-word line circuit, and peripheral circuit of FIG. 2.

FIG. 4A illustrates the structure of an example vertical channel transistor (VCT) according to example embodiments.

FIG. 4B illustrates the structure of an example fin field effect transistor (FinFET) according to example embodiments.

FIG. 5 is a circuit diagram of an example conventional negative sub-word line driver.

FIG. 6 is a circuit diagram of a portion of a core circuit of an example semiconductor memory device according to example embodiments.

FIG. 7 illustrates an example substrate bias structure of the semiconductor memory device shown in FIG. 6.

FIG. 8A is a cross-sectional view along line Y-Y′ shown in FIG. 7, which illustrates the example cell array, sub-word line circuit, and peripheral circuit of FIG. 7.

FIG. 8B is a cross-sectional view along line X1-X1′ shown in FIG. 7, which illustrates the example conjunction circuit and sub-word line circuit of FIG. 7.

FIG. 8C is a cross-sectional view along line X2-X2′ shown in FIG. 7, which illustrates the example cell array and sense amplifier of FIG. 7.

### DETAILED DESCRIPTION OF THE INVENTION

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved

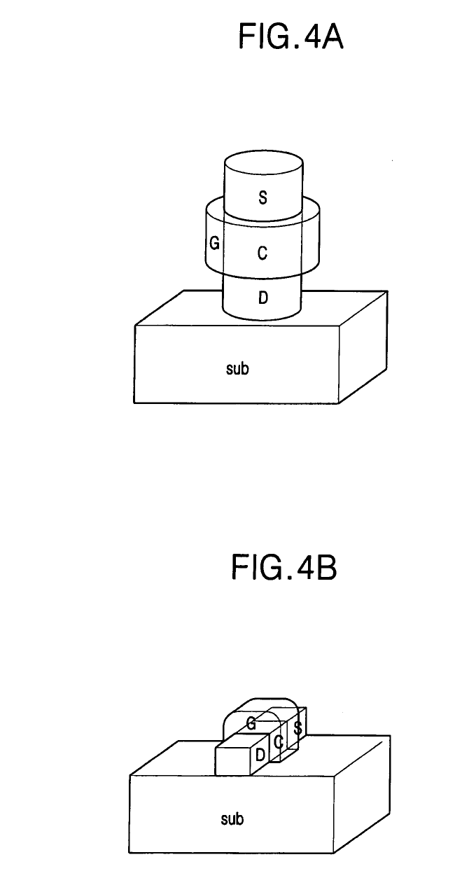

FIG. 4A illustrates the structure of a vertical channel transistor (VCT) and FIG. 4B illustrates the structure of a fin field effect transistor (FinFET), both of which are examples of a three-dimensional transistor.

In the VCT of FIG. 4A, a drain region D may be formed on a semiconductor substrate (or well), a channel region C may be formed on the drain region D, a source region S may be formed on the channel region C, and a gate electrode G may be formed surrounding the channel region C.

The FinFET of FIG. 4B may include a fin active region connected to a semiconductor substrate (or well), which may protrude from the top of the semiconductor substrate, a gate electrode G surrounding a channel region C of the fin active region, and source and drain regions S and D formed in the fin active region on the sides of the gate electrode G.

As stated above, the VCT and the FinFET may have a three-dimensional (or triple) structure in which the channel region C may be formed on the semiconductor substrate and surrounded by the gate electrode G, which may distinguish it from a MOS transistor in which a channel region may be formed in a semiconductor substrate. Thus, the channel characteristics of the VCT and the FinFET may be less affected by a voltage of the semiconductor substrate. Also, a sufficient channel length may be more readily obtained, thus reducing short channel effects. Furthermore, due to the three-dimensional structure of the VCT and the FinFET, the gate electrode G may more readily control the channel region C, thereby enhancing the on/off characteristics of the transistor.

Therefore, by replacing a conventional MOS transistor with a VCT or FinFET as a transistor in a memory cell, the semiconductor memory device may improve the operating reliability and data retention time of a memory cell without applying a negative voltage to the bulk of the transistor in the memory cell.

However, since the width of a channel region of the VCT or FinFET may be significantly smaller than that of a channel region of the MOS transistor, the threshold voltage of the transistor may be dropped from about 0 V to a negative voltage level (for example, about −0.25 V). Therefore, the semiconductor memory device may include a conventional negative sub-word line driver in order to control the operations of the memory cell including the VCT or FinFET.

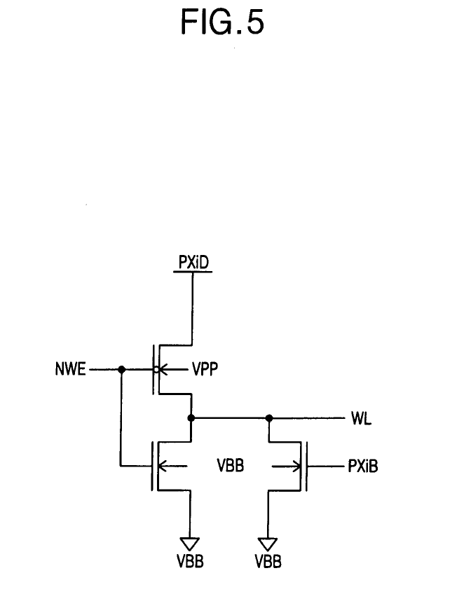

FIG. 5 is a circuit diagram illustrating an example conventional negative sub-word line driver.

Referring to FIG. 5, the negative sub-word line driver may include a p-type MOS transistor PM1, an n-type MOS transistor NM1, and an n-type MOS transistor NM2. The p-type MOS transistor PM1 may apply a high-voltage word line boosting signal PXiD to a word line WL when a word line enable signal NWL is enabled and a boosting voltage VPP or power supply voltage VDD is applied to the bulk of the p-type MOS transistor PM1. The n-type MOS transistor NM1 may apply a back bias voltage VBB of a negative voltage to the word line WL when the word line enable signal NWL is disabled and the back bias voltage VBB is applied to the bulk of the n-type MOS transistor NM1. In addition, the n-type MOS transistor NM2 may apply the back bias voltage VBB to the word line WL in order to prevent floating the word line WL when an inverted word line boosting signal PXiB is enabled and the back bias voltage VBB is applied to the bulk of the n-type MOS transistor NM2.

Thus, the negative sub-word line driver may apply the high-voltage word line boosting signal PXiD to the gate of the n-type MOS transistor through the word line WL during the enabling of the memory cell, while a negative back bias voltage VBB may be applied to the gate of the n-type MOS transistor during the disabling of the memory cell. As a result, the n-type MOS transistor may be turned on in response to the high-voltage word line boosting signal PXiD applied to the gate thereof during the enabling of the memory cell. Similarly, the n-type MOS transistor may be turned off in response to the negative voltage during the disabling of the memory cell.

However, since the back bias voltage VBB of the negative voltage may be applied to the sources of the n-type MOS transistors NM1 and NM2 of the negative sub-word line driver shown in FIG. 5, the back bias voltage VBB may be applied to the bulk of the n-type MOS transistor in order to reduce the forward biasing of a PN junction region of the n-type MOS transistor.

According to example embodiments, a semiconductor memory device may include memory cells using the VCT of FIG. 4A or the FinFET of FIG. 4B and the negative sub-word line driver of FIG. 5.

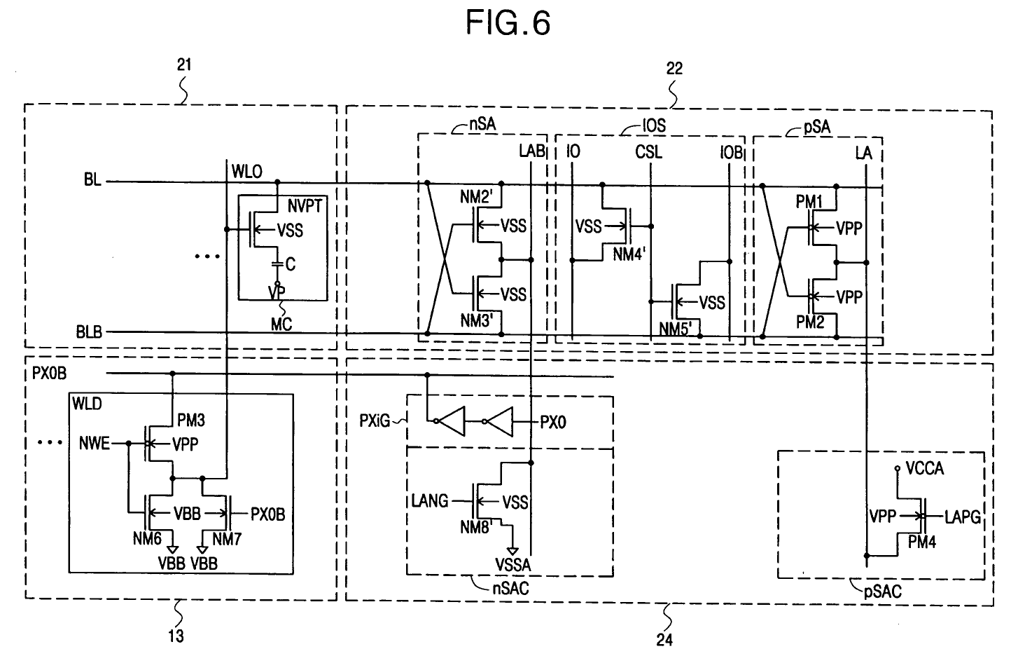

FIG. 6 is a circuit diagram of a portion of a core circuit of a semiconductor memory device according to example embodiments.

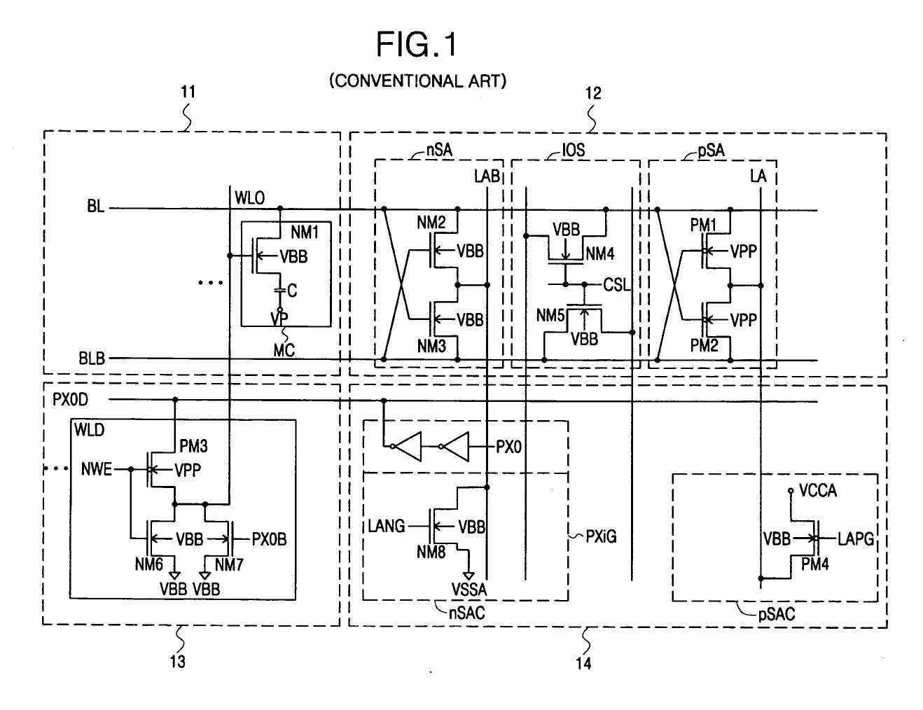

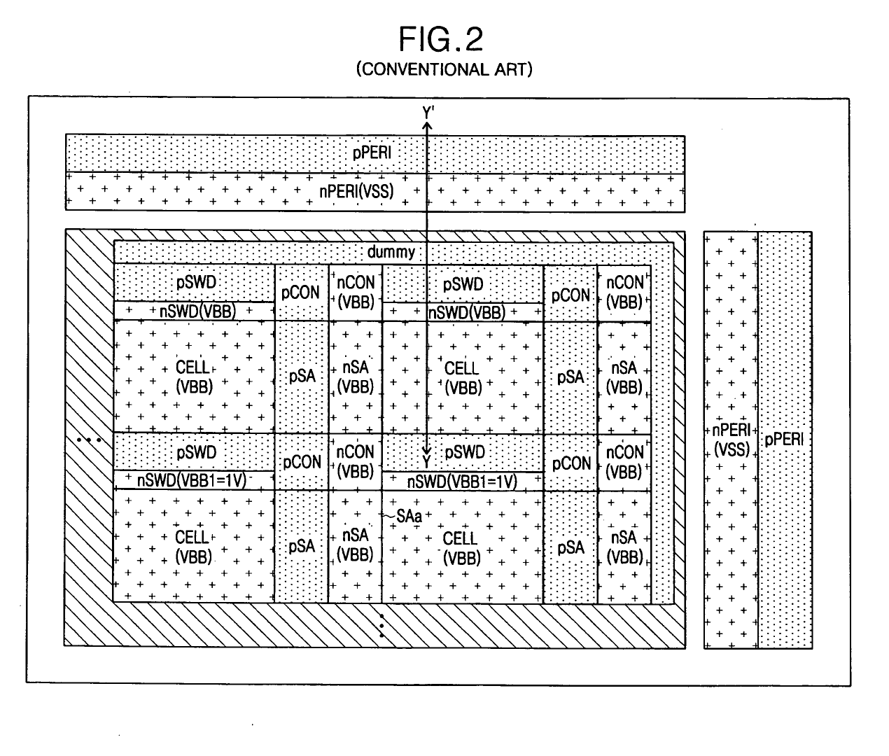

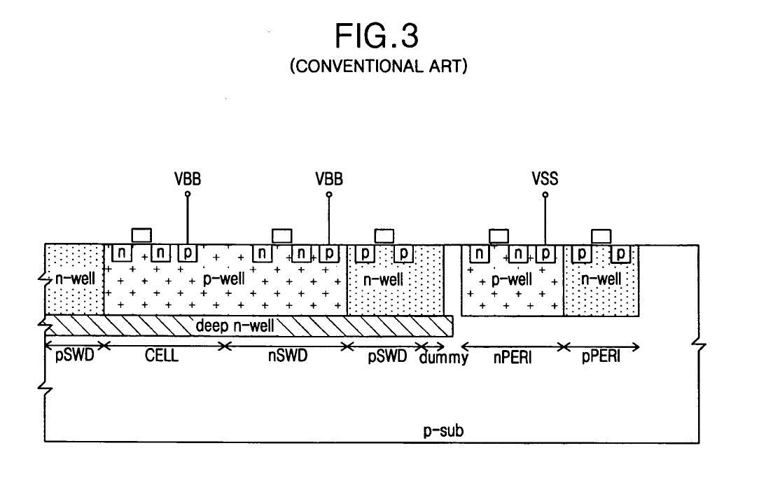

Referring to FIG. 6, the core circuit may include a similar negative sub-word line driver 13 to the core circuit of FIG. 1, but the cell array 11, the sense amplifier 12, and the conjunction circuit 14 shown in FIG. 1 may be replaced by the cell array 21, sense amplifier 22, and conjunction circuit 24 of FIG. 6.

The cell array 21 may include a plurality of memory cells MC, each of which may include an n-type vertical channel transistor (NVCT) (or n-type Fin field effect transistor (NFinFET)), to the bulk of which a ground voltage VSS may be applied, and a capacitor C. The sense amplifier 22 may include an n-type sense amplifier nSA, an input/output selection circuit [OS, and a p-type sense amplifier pSA. The n-type sense amplifier nSA may include n-type MOS transistors NM2′ and NM3′, and to the bulk of each may be applied the ground voltage VSS. The input/output selection circuit IOS may include n-type MOS transistors NM4′ and NM5′, to the bulk of each may be applied the ground voltage VSS. The p-type sense amplifier pSA may include p-type MOS transistors PM1 and PM2, and to the bulk of each may be applied a boosting voltage VPP or power supply voltage VDD.

The sub-word line driver 13 may include a plurality of word line drivers WLD, each of which may further include n-type MOS transistors NM6 and NM7, to the bulk of each may be applied a back bias voltage VBB, and a p-type MOS transistor PM3, to the bulk of which may be applied the boosting voltage VPP or power supply voltage VDD. The conjunction circuit 24 may include an n-type sense amplifier control circuit nSAC, a p-type sense amplifier control circuit PSAC, and a word line boosting signal generation circuit PXiG. The n-type sense amplifier control circuit nSAC may include an n-type MOS transistor NM8′, to the bulk of which the ground voltage VSS may be applied. The p-type sense amplifier control circuit pSAC may include a p-type MOS transistor PM4, to the bulk of which the boosting voltage VPP or power supply voltage VDD may be applied. In addition, the word line boosting signal generation circuit PXiG may include two inverters. Although not shown in the drawings, each of the inverters may include a p-type MOS transistor and an n-type MOS transistor, to the bulk of which the back bias voltage VBB may be applied.

As described above, the core circuit may include the NVCTs, the n-type MOS transistors, and the p-type MOS transistors, and a different voltage (for example, the back bias voltage VBB) may be applied to the bulk of the n-type MOS transistor of the sub-word line driver.

Further, similar to the conventional peripheral circuit, a peripheral circuit (not shown) may include a plurality of n-type MOS transistors, to the bulk of each may be applied the ground voltage VSS, and a plurality of p-type MOS transistors.

A substrate bias structure appropriate for the semiconductor memory device according to example embodiments will now be described.

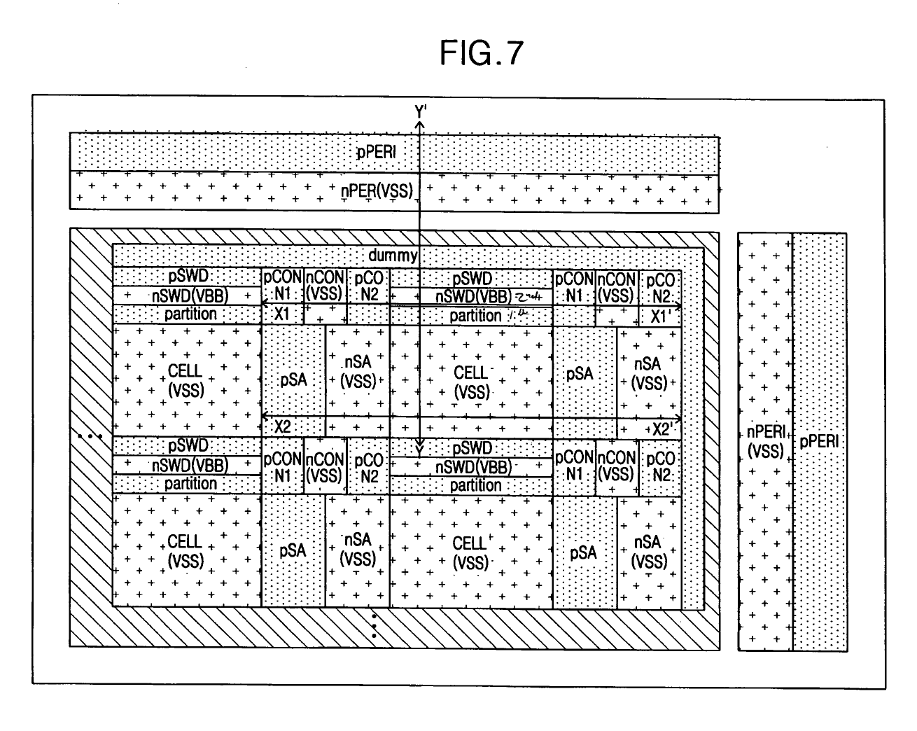

FIG. 7 illustrates a substrate bias structure of the example semiconductor memory device shown in FIG. 6.

In FIG. 7, a region hatched with oblique lines may refer to a deep n-well, a region hatched with dots may refer to an n-well, a region hatched with crosses may refer to a p-well, and an unhatched region may refer to a semiconductor substrate p-sub.

The deep n-well for forming the core circuit may be located in the semiconductor substrate p-sub. P-wells CELL, to which the ground voltage VSS may be applied, and in which the NVCTs or NFinFETs of the cell array 21 may be formed, may be arranged in a matrix on the deep n-well.

P-wells nSA, to which the ground voltage VSS may be applied, and in which the n-type MOS transistors of the sense amplifier 22 may be formed, may be disposed on the deep n-well in a widthwise direction of the p-well CELL of the cell array 21. Thus, the p-wells nSA may be spaced apart from the p-well CELL of the corresponding cell array 21, and may be adjacent to the p-well CELL of the adjacent cell array 21.

P-wells nSWD, to which the back bias voltage VBB may be applied, and in which the n-type MOS transistors of the sub-word line driver 13 may be formed, may be disposed on the deep n-well in a lengthwise direction of the p-well CELL of the cell array 21. Thus, the p-wells nSWD maybe spaced apart from both the p-well CELL of the corresponding cell array 21 and the p-well CELL of the adjacent cell array 21.

P-wells nCON, to which the ground voltage VSS may be applied, and in which the n-type MOS transistor of the conjunction circuit 24 may be formed, may be disposed on the deep n-well in a widthwise direction of the sub-word line driver 13. Thus, the p-wells nCON may be spaced apart from both the p-well nSWD of the corresponding sub-word line driver 13 and the p-well nSWD of the adjacent sub-word line driver 13.

N-wells pSA, in which the p-type MOS transistors of the sense amplifier 22 may be formed, may be disposed on the deep n-well between the corresponding cell array 21 and both the p-wells CELL and the p-wells nSA of the sense amplifier 22.

N-wells “partition”, which may be used for electrical insulation, may be disposed on the deep n-well between the corresponding cell array 21 and both the p-wells CELL and the p-wells nSWD of the sub-word line driver 13. N-wells pSWD, in which the p-type MOS transistors of the sub-word line driver 13 may be formed, may be disposed on the deep n-well between the adjacent cell array 21 and both the p-wells CELL and the p-wells nSWD of the sub-word line driver 13. Thus, the p-wells nSWD of the sub-word line driver 13 may be electrically isolated from the p-wells CELL of the cell array 21.

N-wells pCON1, in which the n-type MOS transistor of the conjunction circuit 24 may be formed, may be disposed on the deep n-well between the corresponding sub-word line driver 13 and both p-wells nSWD and nCON of the conjunction circuit 24. N-wells pCON2, in which the n-type MOS transistor of the conjunction circuit 24 may be formed, may be disposed on the deep n-well between the adjacent sub-word line driver 13 and both p-wells nSWD and p-wells nCON of the conjunction circuit 24. Thus, the p-wells nSWD of the sub-word line driver 13 may also be electrically isolated from the p-wells nCON of the conjunction circuit 24.

As a result, the p-wells nSWD of the sub-word line driver 13, to which the back bias voltage VBB may be applied, may be electrically isolated from the cell array 21 and both the p-wells CELL and the p-wells nCON of the conjunction circuit 24, to which the ground voltage VSS may be applied.

Also, a dummy p-well “dummy” may further be disposed on the deep n-well in order to surround the outer region of the core circuit. Thus, a portion of the semiconductor substrate p-sub in which the core circuit may be formed may be electrically isolated from a portion of the semiconductor substrate p-sub in which the peripheral circuit may be formed.

A p-well nPERI, to which the ground voltage VSS may be applied, and in which the n-type MOS transistors of the peripheral circuit may be formed, and an n-well pPERI, in which the p-type MOS transistors of the peripheral circuit may be formed, may be disposed in a different portion of the semiconductor substrate p-sub than the deep n-well.

In the example semiconductor memory device shown in FIG. 7, the same voltage (for example, the ground voltage VSS) as the voltage applied to the p-well nPERI of the peripheral circuit may be applied to the p-wells CELL, nSA, and nCON of the cell array 21, the sense amplifier 22, and the conjunction circuit 24. However, a different voltage (for example, the back bias voltage VBB) may be applied to the p-wells nSWD of the sub-word line driver 13 that may be electrically isolated from the p-wells CELL, nSA, and nCON of the cell array 21, the sense amplifier 22, and the conjunction circuit 24.

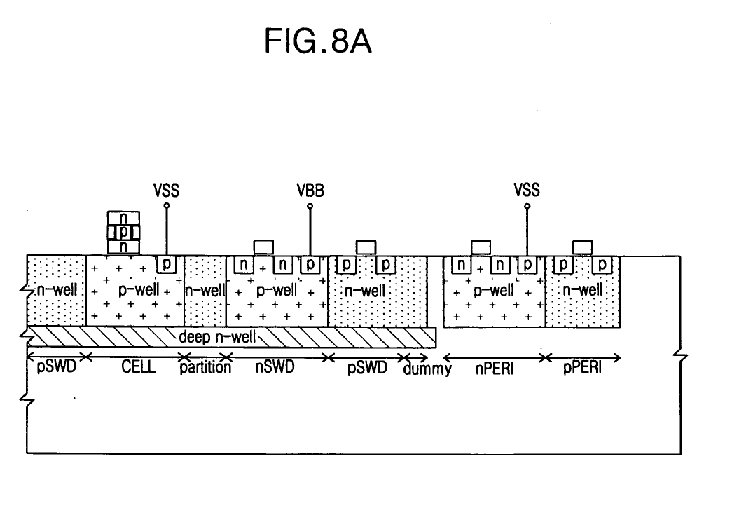

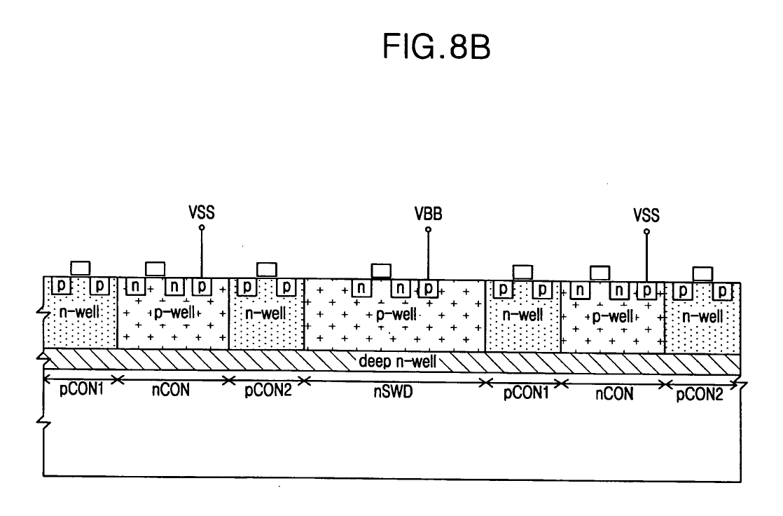

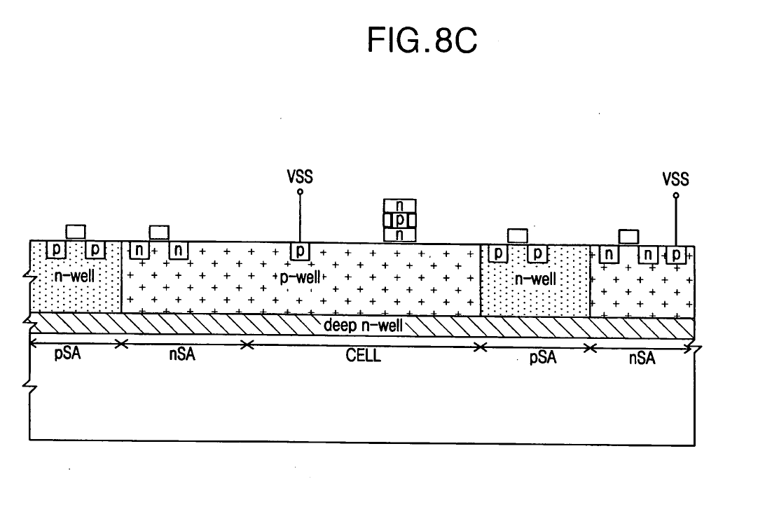

FIGS. 8A through 8C are cross-sectional views of the example semiconductor memory device shown in FIG. 7. FIG. 8A is a cross-sectional view along line Y-Y′ shown in FIG. 7, which illustrates the cell array, the sub-word line circuit, and the peripheral circuit of FIG. 7. FIG. 8B is a cross-sectional view along line X1-X1′ shown in FIG. 7, which illustrates the conjunction circuit and the sub-word line circuit of FIG. 7. FIG. 8C is a cross-sectional view along line X2-X2′ shown in FIG. 7, which illustrates the cell array and the sense amplifier of FIG. 7.

The p-well nSWD of the sub-word line driver may be electrically isolated from the p-well CELL of the cell array by the deep n-well and the n-well “partition” as shown in FIG. 8A. It may also be electrically isolated from the p-well nCON of the conjunction circuit by the deep n-well and the n-well pCON2 of the conjunction circuit as shown in FIG. 8B. A voltage (for example, the back bias voltage VBB), different from the ground voltage VSS applied to the cell array and both the p-wells CELL and the p-wells nCON of the conjunction circuit, may be applied to the p-well nSWD of the sub-word line driver.

Further, the p-well CELL of the cell array may be electrically isolated from the p-well nSWD of the sub-word line driver to which a different voltage (for example, the back bias voltage VBB) may be applied, as shown in FIG. 8A. However, the p-well CELL of the cell array may be adjacent to the p-well nSA of the sense amplifier to which the same voltage (for example, the ground voltage VSS) may be applied, as shown in FIG. 8C.

As explained above, in the semiconductor memory device of the present invention, the memory cell may include three-dimensional transistors and may be configured such that the same voltage may be applied to the p-wells CELL, nSA, nCON, and nPERI of the cell array, the sense amplifier, the conjunction circuit, and the peripheral circuit, while a different voltage may be applied to the p-well nSWD of the negative sub-word line driver.

According to example embodiments, the n-type MOS transistor of the sub-word line driver may have a threshold voltage different from that of the n-type MOS transistor of the peripheral circuit. As a result, in fabricating the semiconductor memory device according to example embodiments, a Vt-adjust ion implantation process may be performed on the n-type MOS transistor formed in a word line driver region SWD.

Because the memory cell of the semiconductor memory device according example embodiments may be configured with VCTs and FinFETs, the memory cell may have improved latch-up immunity, data retention time, and operating speed, and the number of circuits to undergo the Vt-adjust ion implantation process may be reduced.

According to example embodiments, a memory cell of a semiconductor memory device may be configured with three-dimensional transistors, so that a negative voltage may be applied merely to the bulk of an n-type MOS transistor of a sub-word line driver. As a result, a Vt-adjust ion implantation process may need to be performed merely on the n-type MOS transistor of the sub-word line driver. Thus, improvement of the operating reliability and data retention time of the memory cell and simplification of a fabrication process may be achieved.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A semiconductor memory device comprising:
a plurality of memory cells, each having a transistor of a first conductivity type with a first shape;
a sub-word line driver including a transistor of the first conductivity type with a second shape and a transistor of a second conductivity type with the second shape;
a sense amplifier including a transistor of the first conductivity type with the second shape and a transistor of the second conductivity type with the second shape; and
a peripheral circuit including a transistor of the first conductivity type with the second shape and a transistor of the second conductivity type with the second shape, to control inputting/outputting of data in/from the memory cells,
wherein each transistor of the first conductivity type with the first shape, the transistor of the first conductivity type with the second shape in the peripheral circuit, and the transistor of the first conductivity type with the second shape in the sense amplifier have the same bulk voltage; and the transistor of the first conductivity type with the second shape in the sub-word line driver has a negative bulk voltage lower than the bulk voltage of each transistor of the first conductivity type with the first shape.

2. The device according to claim 1, wherein each transistor with the first shape is a vertical channel transistor (VCT).

3. The device according to claim 1, wherein each transistor with the first shape is a fin field effect transistor (FinFET).

4. The device according to claim 1, wherein each transistor with the second shape is a MOS transistor.

5. The device according to claim 1, wherein the sub-word line driver comprises:
the transistor of the second conductivity type with the second shape applying a high voltage to a gate of the transistor of the first conductivity type with the first shape to turn on the transistor of the first conductivity type with the first shape; and
the transistor of the first conductivity type with the second shape receiving the negative bulk voltage as a bulk voltage and applying the negative bulk voltage to the gate of the transistor of the first conductivity type with the first shape to turn off the transistor of the first conductivity type with the first shape.

6. The device according to claim 1, further comprising:
a conjunction circuit located at the intersection of the sub-word line driver and the sense amplifier, and including a transistor of the first conductivity type with the second shape and a transistor of the second conductivity type with the second shape,
wherein the transistor of the first conductivity type with the second shape has the same bulk voltage as the transistor of the first conductivity type with the first shape.

7. A semiconductor memory device comprising:
a deep well of a first conductivity type disposed in a semiconductor substrate of a second conductivity type;
a first well of the second conductivity type disposed on the deep well of the first conductivity type, a transistor of the first conductivity type with a first shape of a memory cell and a transistor of the first conductivity type with a second shape of a sense amplifier being formed in the first well;
a second well of the second conductivity type electrically isolated from the first well of the second conductivity type and disposed on the deep well, a transistor of the first conductivity type with the second shape of a sub-word line driver being formed in the second well; and
a third well of the second conductivity type electrically isolated from the first well of the second conductivity type and the second well of the second conductivity type and disposed in the semiconductor substrate, a transistor of the first conductivity type with the second shape of a peripheral circuit being formed in the third well,
wherein a first voltage is applied to the first well of the second conductivity type and the third well of the second conductivity type, and a negative voltage lower than the first voltage is applied to the second well of the second conductivity type.

8. The device according to claim 7, wherein the transistor with the first shape is a vertical channel transistor (VCT).

9. The device according to claim 8, wherein the VCT comprises:
one of a source region and a drain region disposed on the first well of the second conductivity type;
a channel region disposed on the source region or the drain region;
the other of the drain region and the source region disposed on the channel region; and
a gate electrode surrounding the channel region.

10. The device according to claim 7, wherein the transistor with the first shape is a fin field effect transistor (FinFET).

11. The device according to claim 10, wherein the FinFET comprises:
a fin active region of the second conductivity type connected to the first well of the second conductivity type and protruding from a top surface of the first well of the second conductivity type;
a gate electrode surrounding a channel region disposed in the fin active region; and
a source region and a drain region disposed in the fin active region on both sides of the gate electrode.

12. The device according to claim 7, wherein the transistor with the second shape is a MOS transistor.

13. The device according to claim 7, further comprising:
a first well of the first conductivity type disposed on the deep well between the first well of the second conductivity type and the second well of the second conductivity type to electrically isolate the first well of the second conductivity type from the second well of the second conductivity type, a transistor of the second conductivity type with the second shape of the sub-word line driver being formed in the first well;
a second well of the first conductivity type disposed on the deep well adjacent to the first well of the second conductivity type, a transistor of the second conductivity type with the second shape of the sense amplifier being formed in the second well; and
a third well of the first conductivity type electrically isolated from the first well of the first conductivity type and the second well of the first conductivity type and disposed in the semiconductor substrate, and a transistor of the second conductivity type with the second shape of the peripheral circuit being formed in the third well.

14. The device according to claim 13, wherein the first well of the first conductivity type comprises:
a fourth well of the first conductivity type disposed on the deep well between the first well of the second conductivity type and the second well of the second conductivity type to electrically isolate the first well of the second conductivity type from the second well of the second conductivity type; and
a fifth well of the first conductivity type disposed on the deep well between the first well of the second conductivity type in which the fourth well of the first conductivity type is not disposed and the second well of the second conductivity type to electrically isolate the first well of the second conductivity type from the second well of the second conductivity type, a transistor of the second conductivity type with the second shape of the sub-word line driver being formed in the fifth well.

15. The device according to claim 7, further comprising:
a fourth well of the second conductivity type disposed on the deep well to electrically isolate the first well of the second conductivity type from the second well of the second conductivity type, a transistor of the first conductivity type with the second shape of a conjunction circuit being formed in the fourth well; and
a sixth well of the first conductivity type disposed on the deep well between the fourth well of the second conductivity type and the second well of the second conductivity type to electrically isolate the fourth well of the second conductivity type from the second well of the second conductivity type, a transistor of the second conductivity type with the second shape of the conjunction circuit being formed in the sixth well.

16. A method of forming a semiconductor memory device, comprising:
forming a deep well of a first conductivity type in a semiconductor substrate of a second conductivity type;
forming a transistor of the first conductivity type with a first shape of a memory cell and a transistor of the first conductivity type with a second shape of a sense amplifier in a first well of the second conductivity type on the deep well of the first conductivity type;
forming a transistor of the first conductivity type with the second shape of a sub-word line driver in a second well of the second conductivity type, electrically isolated from the first well of the second conductivity type, on the deep well of the first conductivity type; and
forming a transistor of the first conductivity type with the second shape of a peripheral circuit in a third well of the second conductivity type, electrically isolated from the first well of the second conductivity type and the second well of the second conductivity type, in the semiconductor substrate,
wherein the transistor of the first conductivity type with the first shape, the transistor of the first conductivity type with the second shape in the peripheral circuit, and the transistor of the first conductivity type with the second shape in the sense amplifier have the same bulk voltage; and the transistor of the first conductivity type with the second shape in the sub-word line driver has a negative bulk voltage lower than the bulk voltage of the transistor of the first conductivity with the first shape.
